(19) United States
(12) Patent Application Publication
(10) Pub. No.: US 2007/0036944 A1
(43) Pub. Date: Feb. 15, 2007

(54) Assembly of an electrical component comprising an electrical insulation film on a substrate and method for producing said assembly

(76) Inventors: Franz Auerbach, Villach (AT); Reinhold Bayerer, Warstein (DE); Thomas Licht, Warstein (DE); Karl Weidner, Munich (DE)

Correspondence Address: STAAS & HALSEY LLP, SUITE 700, 1201 NEW YORK AVENUE, N.W., WASHINGTON, DC, 20005, US

(21) Appl. No.: 10/571,668

(22) PCT Filed: Sep. 1, 2004
(86) PCT No.: PCT/EP04/51979

§ 371 Date: Mar. 13, 2006

(30) Foreign Application Priority Data
Sep. 12, 2003 (DE) 103 42 295.1

(51) Int. Cl. D04G 1/00; G11B 5/64

(52) U.S. Cl. 428/141; 442/1; 428/192

(57) ABSTRACT

An electrical component is mounted on a substrate. At least one electrical insulation film is provided to electrically insulate the component and at least section of the insulation film is connected to the component and the substrate, in such a way that the surface contours of said section of the insulation film are moulded to the surface contours formed by the component and the substrate. The insulation film has dielectric strength in relation to an electric field strength of more than 10 kV/mm and preferably more than 50 kV/mm. To produce the assembly, the insulation film is laminated onto the substrate, preferably by means of a vacuum. The component is in particular a power semiconductor component.

### CROSS REFERENCE TO RELATED APPLICATIONS

This application is based on and hereby claims priority to PCT Application No. PCT/EP2004/051979 filed on Sep. 1, 2004 and German Application 10342295.1 filled on Sep. 12, 2003, the contents of which are hereby incorporated by reference.

### BACKGROUND OF THE INVENTION

The invention relates to an arrangement of an electrical component on a substrate, wherein at least one electrical insulating film is present for the purpose of electrically insulating the component and at least one section of the insulating film is joined to the component and the substrate in such a way that a surface contour formed by the component and the substrate is reproduced in a surface contour of said section of the insulating film. In addition, a method for producing said arrangement is specified.

An arrangement of said kind and a method for producing said arrangement are known, for example, from WO03/030247 A2. The substrate is, for example, a DCB (Direct Copper Bonding) substrate which is formed of a carrier layer made of a ceramic, to both sides of which electrically conducting layers made of copper are applied. A semiconductor component, for example, is soldered onto one of these electrically conducting copper layers in such a way that an electrical contact surface of the semiconductor component facing away, from the substrate is present.

An insulating film on a polyimide or epoxy base is laminated under vacuum onto this arrangement formed of the semiconductor component and the substrate such that the insulating film covers and is tightly joined to said semiconductor component and said substrate. The insulating film is bonded to the semiconductor component and the substrate by a positive and force fit. The surface contour (topology) formed by the semiconductor component and the substrate is reproduced in the surface contour of the insulating film. The insulating film follows the surface contour of the semiconductor component and of the substrate.

The insulating film of the known device is formed of an electrically insulating plastic. In order to achieve an electrical contacting of the contact surface of the semiconductor component, a window is opened in the insulating film. As a result the contact surface of the semiconductor component is exposed. In a following step, electrically conducting material is applied to the contact surface.

The high voltages necessary for activating and driving the power semiconductor component can cause a particularly strongly pronounced field overshoot at a metallization edge of the power semiconductor component or a connecting line of the power semiconductor component. Electrical arcing can occur as a result of the field overshoot. This can lead to the destruction of the electrical component.

As an alternative to the lamination technique presented above, insulating layers made of an applied electrically insulating resist are also used for the electrical insulation of electrical components. However, an insulating layer made of a resist can be thinned out, particularly at a metallization edge. The thinning out can be caused, for example, as a result of the resist flowing off when being applied to the metallization edge. The thinning out results in a reduced dielectric strength, which can be counteracted only by additional measures, for example by applying a particularly thick resist layer.

### SUMMARY OF THE INVENTION

One possible object of the present invention is to illustrate how an electrical component on a substrate can be effectively protected against field overshoots.

The inventors propose an electrical device having an electrical component on a substrate wherein at least one electrical insulating film is present for electrically insulating the component and at least one section of the insulating film is joined to the component and the substrate in such a way that a surface contour formed by the component and the substrate is reproduced in a surface contour of the section of the insulating film. The arrangement is characterized in that at least the section of the insulating film having the surface contour has a dielectric strength against an electrical field strength of at least 10 kV/mm.

The inventors also propose a method for producing the device, comprising the following steps: a) providing an arrangement of at least one electrical component on a substrate and b) laminating the insulating film onto the component and the substrate in such a way that the surface contour formed by the component and the substrate is reproduced in the surface contour of the insulating film.

The method and device are based on the knowledge that a dielectric strength necessary for the operation of the component can be ensured with the aid of an insulating film particularly at exposed points of the component, which is to say at a corner, edge or tip of the component. The high dielectric strength is achieved by the film material, the film strength and above all by the binding of the insulating film to the component. An insulating film suitable for high voltages is preferably used. High voltage, in this context, is to be understood as meaning a voltage of several hundred volts. Owing to the lamination of the insulating film onto the component and the substrate a permanent, tight contact with the electrical component is achieved. This also applies to the exposed points of the component. The result is a tight and permanent bond between the insulating film and the component that is necessary to obtain the high dielectric strength. With the aid of the laminated-on insulating film the electrical insulation of the component is preserved even at an activation or drive voltage of several hundred volts. No electrical arcing takes place.

In a special embodiment the electrical field strength is selected from the range from 10 kV/mm inclusive to 200 kV/mm inclusive. The field strength is preferably at least 50 kV/mm. The insulating film possesses a high dielectric strength against such field strengths. A dielectric strength able to withstand higher field strengths may also be present, however.

The high dielectric strength may be present along the whole of the insulating film. However, the high dielectric strength is present in particular at exposed points of the insulating film. Therefore the surface contour formed by the component and the substrate preferably has at least one geometric shape from the group corner and/or edge. It is particularly at such points of the component that field overshoots can occur. It is therefore important to ensure the necessary dielectric strength is present at these points by a suitably adapted insulating film and its bonding to the component and the substrate.

In a special embodiment, in order to increase the dielectric strength, at least the section of the insulating film having the surface contour has a multi-layer structure. The dielectric strength is increased by a plurality of insulating films superimposed on top of one another. In this arrangement the multi-layer structure can also extend over the entire insulating film. The multi-layer structure is created in particular by repeated lamination of individual insulating films onto the substrate. All in all, an insulating film formed of a plurality of individual layers is produced. The individual layers of the multi-layer insulating film can be formed of the same film material. However, it is also conceivable that the individual layers of the insulating film have different film materials.

In a special embodiment, at least the section of the insulating film having the surface contour has an essentially constant film strength. No thinning out of the insulating layer occurs, as may happen in the case of resist coating at exposed points. An effective electrical insulation of the component is guaranteed.

In a special embodiment, at least the section of the insulating film having the surface contour has a different film strength compared to a further section of the insulating film. The insulating film is selectively strengthened at the points at which field overshoots can occur during the operation of the component. In this case a strengthening can be achieved by introducing a multi-layer structure as described above. The strengthening can also be achieved through the use of a preformed insulating film, however. In a special embodiment, therefore, at least the section of the insulating film having the surface contour is preformed. The preformed insulating film is, for example, thermally preformed. In this case the preforming comprises in particular a prestamping and/or prestructuring.

Any desired duroplastic (duromers) and/or thermoplastic plastic is/are conceivable as the plastic of the insulating film. In a special embodiment, the insulating film has at least one plastic selected from the group polyacrylate, polyimide, polyethylene, polyphenol, polyetheretherketon, polytetrafluorethylene and/or epoxy. Mixtures of the plastics and/or copolymers from monomers of the plastics are likewise possible.

In a further embodiment the insulating film has a composite material containing the plastic and at least one filler material that is different from the plastic. Either on its own or in combination with other materials, the composite material is used to form the insulating film. In the case of the composite material, the plastic forms a matrix into which the filler material is embedded. The plastic is the base material of the composite material. In this arrangement the filler material can serve as an extending agent. In particular, however, the filler material is used to influence an electrical and/or mechanical property of the insulating film. Conceivable here in particular is the use of an electrically insulating and thermally conductive filler material. The result is an electrically insulating, yet thermally conductive insulating film. By using an insulating film having a thermally conductive filler material it is possible to dissipate heat that is generated during the operation of the component from the component. The thermal conductivity λ of the filler material at room temperature amounts to at least 1 W·m⁻¹·K⁻¹. In order to exploit the thermal conductivity of the filler material, a fill level (content) of the filler material in the plastic is chosen such that a coagulation limit of the filler material in the base material is exceeded. Below the coagulation limit a probability that the individual filler material particles touch one another is very small. If the coagulation limit is exceeded, there is a relatively high probability that the filler material particles will touch one another. From this results a relatively high specific thermal conductivity coefficient of the composite material. A relatively high thermal conductivity with, at the same time, a low electrical conductivity can be achieved in particular with a filler material made of a ceramic material. A material of this kind is, for example, aluminum oxide (Al₂O₃) in powder form. For efficient heat dissipation, the insulating film is advantageously connected in a thermally conducting manner to a heat sink.

Any organic or inorganic filler material is conceivable as the filler material. For example, the filler material itself is a plastic. The inorganic filler material can be any inorganic compound, for example a carbonate, oxide, sulfide or the like. As described above, inorganic filler materials in the form of ceramic materials are particularly suitable. Metal organic compounds, for example silicon organic compounds, are likewise possible as filler material. Conceivable in particular is also the use of different filler materials or the use of mixtures of filler material. In this case the different fillers can differ from one another in terms of their respective material and/or in terms of their respective form.

The filler material can be in powder form or fibrous. A diameter of the filler material particles amounts to several nm to a few μm. The diameter of the filler material particles is, like the filler of the filler material and a content of the filler in the base material, dimensioned such that the insulating film exhibits the high dielectric strength and at the same time can be laminated onto the component and substrate. This means that an elasticity of the insulating film is preserved even in the presence of the filler material, with the result that the insulating film can follow the surface contour of component and substrate.

The insulating film is preferably embodied through selection of its film strength and its film material such that a height difference of up to 1000 μm can be overcome. The height difference is due, among other things, to the topology of the substrate and the component mounted on the substrate. At the same time the height difference can be caused by one or more stages.

The surface contour formed by the component and the substrate preferably has a height difference which is chosen from the range from 200 μm inclusive to 1000 μm inclusive.

In a special embodiment, the filler material is present in the form of a mesh. In a mesh, individual fibers of the filler material are woven and/or interwoven with one another. With the aid of the woven material it is ensured that no thinning out of the insulating film occurs at exposed points of the component when the insulating film is laminated onto the component. In this way the high dielectric strength of the insulating film is preserved. At the same time, thanks to the use of a thermally conducting filler material, heat generated during the operation of the component can be efficiently dissipated through thermal conduction via the fibers of the mesh.

Any passive and/or active electrical component is possible as a component. A semiconductor component is preferably used as the component. The semiconductor component is preferably a power semiconductor component chosen from the group MOSFET, IGBT and/or bipolar transistor. The above described electrical device is particularly suitable for components of this type on a substrate. With the aid of the insulating films an efficient electrical insulation of the power semiconductor components can be realized in a simple manner at the same time as an electrical contacting of different contact surfaces of the power semiconductor component. In addition, further functions can be integrated in the insulating film, for example a thermal dissipation of heat that is necessary for the operation of the power semiconductor component.

The laminating on of the insulating film leads to a tight and permanent contact between the insulating film and the component and between the insulating film and the substrate.

If the component is completely covered by the insulating film as a result of the lamination, in this way said component can be hermetically shielded from external influences. In this way it is possible, for example, to prevent a penetration of water, for example from a humid atmosphere, as far as the component. This contributes to an improved dielectric strength of the insulating film or, as the case may be, the bond formed from insulating film and component.

In order to improve the tight contact between the insulating film and the component or the substrate, an adhesive can be applied to the insulating film and/or the component or the substrate before the lamination step. For example, an insulating film with an adhesive coating is used. In order to improve the contact, however, in a special embodiment of the production method the lamination is performed under a vacuum. In this way a particularly tight and permanent contact is produced between the insulating film and the substrate and the component. As a result of the lamination under vacuum it can be ensured that the surface contour formed by the substrate and the component is reproduced by the insulating film. The surface contour of the insulating film follows the surface contour of the component and of the substrate. The lamination is advantageously performed in a vacuum press. For this purpose vacuum pulling, hydraulic vacuum pressing, vacuum gas pressure pressing or similar lamination methods are conceivable. The pressure is advantageously applied isostatically. The lamination is performed, for example, at temperatures of 100° C. to 250° C. and at a pressure of 1 bar to 10 bar. The precise process parameters of the lamination, i.e. pressure, temperature, time, etc. are dependent, inter alia, on the surface contour of the substrate, the film material of the insulating film and the film strength of the insulating film.

A film strength of the insulating film chosen from the range from 25 μm to 150 μm proves to be particularly advantageous here. Greater film strengths of up to 500 μm are also possible. In order to obtain a specific overall strength, the lamination of thinner insulating films can be performed a plurality of times.

In a special embodiment, a tempering step is performed during and/or after the insulating film has been laminated on. It is conceivable, for example, that an insulating film is used with a non- or only partially cross-linked plastic. The cross-linking of the plastic is improved by increasing the temperature. The tight contact between the insulating film and the substrate and the component is produced by further cross-linking of the plastic. A continued polymerization by exposure to light is conceivable in addition to the continued polymerization by increasing the temperature.

In order to improve the adhesion of the insulating film on the component and on the substrate, a bonding layer can be applied on the insulating film and/or on the component or on the substrate before the lamination is performed. Any single- or multi-component adhesive is conceivable in this case. A bonding layer using a polysilane reveals itself as particularly advantageous. The bonding layer produces not only a positive and frictional contact, but in addition also a materially bonded contact. This results likewise in an improved dielectric strength.

To sum up, the following special advantages are produced

A structure that is suitable for high-voltage applications is obtained as a result of the electrical insulation of the component of the electrical device with the aid of a laminated-on electrical insulating film having high dielectric strength.

In particular an efficient electrical insulation in the area of exposed points of the component is possible here, with the result that no electrical arcing occurs in spite of field overshoot.

The dielectric strength of the insulating film can be selectively increased by simple measures, for example through the use of suitable filler materials, the use of a preformed insulating film and/or the use of a multi-layer insulating film.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIGS. 1 to 3 in each case show a section of an arrangement of an electrical component on a substrate in a side cross-section.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

The electrical device 1 has an electrical component 3 on a substrate 2. The substrate 2 is a DCB substrate with a carrier layer 21 made of a ceramic and an electrically conducting layer made of copper applied on top of the carrier layer 21.

The electrical component 3 is a power semiconductor component 32 in the form of a MOSFET. The power semiconductor component 32 is soldered onto the electrically conducting copper layer 22 in such a way that a contact surface 31 of the power semiconductor component 32 faces away from the substrate 2. One of the contacts of the power semiconductor component 32 (source, gate, drain) is electrically contacted via the contact surface 31.

A connecting line 4 is present on the substrate 2 for the purpose of electrically contacting the contact surface 31 of the power semiconductor component 32.

An approximately 50 μm thick insulating film 5 made of a composite material is laminated onto the substrate 2 and the power semiconductor component 32 in such a way that the surface contour 11, which is produced from the power semiconductor component 32, the electrically conducting layer 22 and the carrier layer 21 of the DCB substrate, is reproduced in the surface contour 51 of a section 52 of the insulating film 5. The surface contour 11 has a height difference 12 of approximately 500 μm.

In order to produce the circuit arrangement 1, the power semiconductor component 32 is soldered onto the electrically conducting layer 22 of the DCB substrate 2 in such a way that the contact surface 31 of the power semiconductor component 32 faces away from the substrate 2.

A subsequent step the insulating film 5 is laminated onto the contact surface 31 of the semiconductor component 32 and the substrate 2 under vacuum. In the process a tight bond is produced between the insulating film 5 and the power semiconductor component 32 or the substrate 2. A positive and frictional contact is established between the insulating film 5 and the component 32 or the substrate 2. The insulating film 5 bonds to the power semiconductor component 32 and the substrate 2 in such a way that the surface contour 11 which is essentially produced by the shape of the power semiconductor component 3 is reproduced by the surface contour 51 of the insulating film 5.

The insulating film 5 is an insulating film suitable for high voltages. The insulating film 5 has a dielectric strength against a field strength of up to 50 kV/mm. As a result of the lamination of the insulating film 5, this high dielectric strength is also guaranteed in the partial area in which a corner 33 or edge 34 of the component 3 is located. Extreme field overshoots occur at these points when the power semiconductor component 32 is activated.

### EXAMPLE 1

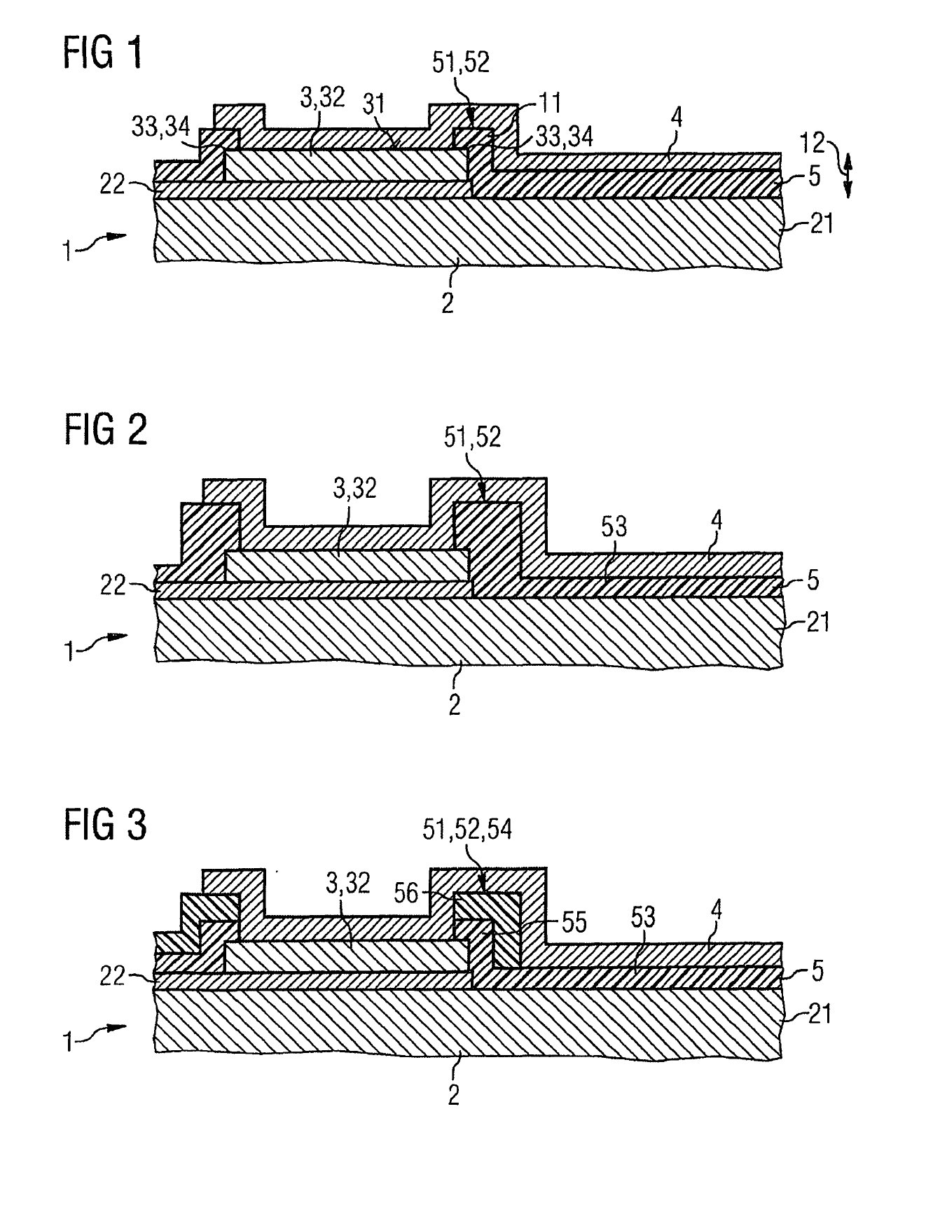

The insulating film 5 is single-layer (FIG. 1). In this case the insulating film 5 is formed of a composite material. The base material of the composite material is a plastic made of polyimide. Aluminum oxide in powder form is contained in the plastic as the filler material. Particle size and fill level of the aluminum oxide are chosen here to ensure that the coagulation limit is exceeded. Owing to the thermal conductivity of the aluminum oxide an insulating film 5 is present which serves not just for electrical insulation. Heat generated during the operation of the power semiconductor component 32 can be efficiently dissipated to a heat sink (not shown) by way of the insulating film 5.

### EXAMPLE 2

The insulating film 5 also has a composite material. The base material of the composite material is likewise a polyimide. In contrast to the preceding example, the filler used in the composite material is a mesh made of polytetrafluorethylene fibers. The mesh lowers the probability of the insulating film being thinned out during lamination. The result is an efficient electrical insulation of the component 32.

### EXAMPLE 3

In contrast to the preceding examples, the section 52 of the insulating film 5 is strengthened by the surface contour 51. Said section 52 is located in the area of the electrical component 3 in which field overshoots due to electrical activation with high voltages can occur as a result of the geometric shape of the component 3. This leads to an improved dielectric strength in the area of the section 52 of the insulating film 5.

In order to achieve the strengthening, a preformed insulating film 5 is laminated on (FIG. 2). The preformed insulating film 5 has a section 52 having a film strength that is different from a further section 53 of the insulating film 5. The film strengths of the section 52 and of the further section 53 of the insulating film 5 are different. The section 52 of the insulating film 5 by which the corners 33 and edges 34 of the component 3 are electrically insulated has a higher film strength than the further section 53 of the insulating film 5 by which an insulation of the electrical connecting line 4 is achieved in which the probability of a field overshoot occurring is low.

### EXAMPLE 4

In order to achieve a strengthening of the section 51 of the insulating film 5, in contrast to the preceding example, an insulating film 5 having a multi-layer section 52 is used (FIG. 3). The section 52 of the insulating film 5 has a multi-layer structure 54. The individual layers 55 and 56 of the section 52 of the insulating film 5 is formed of the same film material. An overall film strength of the insulating film amounts to approximately 100 μm. In order to produce this electrical device 1, two insulating films, each approximately 50 μm thick, are laminated on in turn, a structured insulating film being used as the second insulating film.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-17. (canceled)

18. An electrical device comprising:
a substrate;
an electrical component mounted on the substrate so as to define a surface contour between the electrical component and the substrate; and
at least one electrical insulating film provided on the substrate and on the electrical component to electrically insulate the electrical component, the insulating film having a border section in contact with the electrical component and the substrate where the insulating film has a surface contour following the surface contour formed between the electrical component and the substrate, wherein
the border section of the insulating film has a dielectric strength to withstand an electrical field strength of at least 10 kV/mm.

19. The electrical device as claimed in claim 18, wherein the field strength is within a range of from 10 kV/mm inclusive to 200 kV/mm inclusive.

20. The electrical device as claimed in claim 18, wherein the surface contour formed between the electrical component and the substrate has at least one geometric shape chosen from the group consisting of a corner and an edge.

21. The electrical device as claimed in claim 18, wherein at least the border section of the insulating film is formed of a multi-layer structure.

22. The electrical device as claimed in claim 18, wherein at least the border section of the insulating film has an essentially constant film strength.

23. The electrical device as claimed in claim 18, wherein the border section of the insulating film has a different film strength compared to a further section of the insulating film.

24. The electrical device as claimed in claim 18, wherein at least the border section of the insulating film is preformed.

25. The electrical device as claimed in claim 18, wherein the insulating film is formed of at least one plastic selected from the group consisting of polyacrylates, polyimides, polyethylenes, polyphenols, polyetheretherketones, polytetrafluorethylenes and epoxies.

26. The electrical device as claimed in claim 18, wherein the insulating film is formed of a composite material containing a plastic and at least one filler material different from the plastic.

27. The electrical device as claimed in claim 26, wherein the filler material has a mesh form.

28. The electrical device as claimed in claim 26, wherein the filler material is thermally conductive.

29. The electrical device as claimed in claim 18, wherein the surface contour formed between the electrical component and the substrate has a height difference in a range of from 200 μm inclusive to 1000 μm inclusive.

30. The electrical device as claimed in claim 18, wherein the electrical component is a semiconductor component.

31. The electrical device as claimed in claim 30, wherein the semiconductor component is a power semiconductor component selected from the group consisting of MOSFETs, IGBTs and bipolar transistors.

32. The electrical device as claimed in claim 19, wherein at least the border section of the insulating film is formed of a multi-layer structure.

33. The electrical device as claimed in claim 32, wherein at least the border section of the insulating film has an essentially constant film strength.

34. A method for producing an electrical device, comprising:
mounting an electrical component on a substrate so as to define a surface contour between the electrical component and the substrate; and
laminating an insulating film onto the electrical component and onto the substrate to electrically insulate the electrical component, the insulating film having a border section with a surface contour following the surface contour formed between the electrical component and the substrate,
wherein the border section of the insulating film has a dielectric strength to withstand an electrical field strength of at least 10 kV/mm.

35. The method as claimed in claim 34, wherein the insulating film is laminated in a partial vacuum.

37. The method as claimed in claim 34, wherein a tempering step is performed during and/or after the insulating film is laminated.
